(19) United States
(12) Patent Application Publication
(10) Pub. No.: US 2024/0175844 A1
(43) Pub. Date: May 30, 2024

(54) CIRCUITRY FOR MEASUREMENT OF ELECTROCHEMICAL CELLS

(71) Applicant: Cirrus Logic International Semiconductor Ltd., Edinburgh (GB)

(72) Inventors: John P. LESSO, Edinburgh (GB); Toru IDO, Kanagawa (JP)

(73) Assignee: Cirrus Logic International Semiconductor Ltd., Edinburgh (GB)

(21) Appl. No.: 18/506,525

(22) Filed: Nov. 10, 2023

Related U.S. Application Data
(60) Provisional application No. 63/428,245, filed on Nov. 28, 2022.

(51) Int. Cl. G01N 27/416

(52) U.S. Cl. CPC G01N 27/4163

(57) ABSTRACT

Circuitry for characterising an electrochemical cell having a first electrode, a second electrode and a non-linear response characteristic, the circuitry comprising: difference circuitry configured to measure a potential difference across the electrochemical cell and output a difference voltage proportional to the measured potential difference; compensation circuitry configured to linearise the difference voltage and output a linearised difference signal; and a first analog-to-digital converter (ADC) configured to convert the linearised difference signal to a digital output.

### TECHNICAL FIELD

The present disclosure relates to circuitry for measuring characteristics in electrochemical cells.

### BACKGROUND

Electrochemical sensors are widely used for the detection or characterisation of one or more particular chemical species, analytes. Such sensors comprise an electrochemical cell, typically consisting of two or more electrodes configured for contact with an analyte whose concentration is to be ascertained. For electrochemical cells, potentiometry can be used to measure a potential difference between an electrode and an analyte with no external bias and with no current flow. A working electrode (indicator electrode) of the electrochemical cell can be used as a proxy for the electrode, and a reference electrode can be used as a proxy for the analyte. Thus, the potential difference between the working electrode and the reference electrode gives an indication of a property of the electrode and the analyte.

In a typical electrochemical cell comprising an ion-selective electrode as the working electrode, measured potential difference varies logarithmically with analyte concentration. As such, when analyte concentration is high, changes in analyte concentration cause relatively small changes in measured potential when compared to changes at low analyte concentrations. As such, high resolution analog-to-digital converters (ADCs) are typically required to track such small changes in potential at high analyte concentrations.

### SUMMARY

According to a first aspect of the disclosure, there is provided circuitry for characterising an electrochemical cell having a first electrode, a second electrode and a non-linear response characteristic, the circuitry comprising: difference circuitry configured to measure a potential difference across the electrochemical cell and output a difference voltage proportional to the measured potential difference; compensation circuitry configured to linearise the difference voltage and output a linearised difference signal; and a first analog-to-digital converter (ADC) configured to convert the linearised difference signal to a digital output.

A response characteristic of the compensation circuitry may be substantially inverse to the non-linear response of the electrochemical cell.

The non-linear response characteristic of the electrochemical cell may be a logarithmic response characteristic. In which case, the response characteristic of the compensation circuitry may be an exponential response characteristic.

The exponential response characteristic may be provided by a non-linear circuit element of the compensation circuitry.

The non-linear circuit element may comprise one or more of a diode, a voltage controlled oscillator (VCO), a translinear loop or any combination thereof.

The non-linear circuit element may comprise a bipolar junction transistor (BJT). A base of the BJT may be coupled to a collector of the BJT.

The non-linear circuit element may comprise a field effect transistor (FET) configured for operation in a subthreshold mode. A gate of the FET may be coupled to a source or a drain of the FET.

The non-linear circuit element may comprise a combination of diodes coupled in series and/or parallel.

The difference circuitry may comprise a first amplifier comprising: a first input for receiving a first voltage derived from the first electrode; and a second input for receiving a second voltage derived from the second electrode. The first amplifier may be a dual differential amplifier, wherein the first input is a first non-inverting input, and wherein the second input is a first inverting input. The first amplifier may further comprise: a second non-inverting input coupled to an output of the first amplifier via a feedback resistor, the second non-inverting input coupled to a first reference voltage via a bias resistor; and a second inverting input coupled to the reference voltage or a second reference voltage.

The difference circuitry may comprise an instrumentation amplifier.

The difference circuitry may comprise: a first pulse-width modulated (PWM) ADC having a first input coupled to the first electrode and an output configured the output a first time encoded signal encoded based on a first voltage at the first electrode; and a second pulse-width modulated (PWM) ADC having a first input coupled to the second electrode and an output configured the output a second time encoded signal encoded based on a second voltage at the second electrode.

According to another aspect of the disclosure, there is provided circuitry for processing a signal from a sensor having a non-linear response characteristic, the circuitry comprising: an analog-to-digital converter (ADC) comprising: an ADC input; an ADC output; and a feedback path between the ADC input and the ADC output, the feedback path comprising a digital to analog converter (DAC); and a non-linear circuit element coupled between the feedback path and a reference voltage, the non-linear circuit element configured to compensate for the non-linear response characteristic of the sensor.

The reference voltage may be ground (i.e. zero volts).

The non-linear circuit element may comprise one or more diodes, the one or more diodes comprising: a cathode coupled to the feedback path; and an anode coupled to the reference voltage.

The non-linear circuit element may comprise a PNP bipolar junction transistor (BJT) comprising: an emitter coupled to the feedback path; and a base and a collector, the base and the collector coupled to the reference voltage.

The non-linear circuit element comprises a NPN bipolar junction transistor (BJT) comprising: an emitter coupled to the reference voltage; and a base and a collector, the base and the collector coupled to the emitter.

The non-linear circuit element may comprise a field effect transistor (FET) configured for operation in a subthreshold mode, the FET comprising a gate, a source, and a drain. The gate and a first one of the source and drain may be coupled to the reference voltage, and a second one of the source and drain different from the first one is coupled to the feedback path.

The non-linear circuit element may comprise a diode or a voltage controlled oscillator (VCO), or a translinear loop.

According to another aspect of the disclosure, there is provided circuitry for characterising an electrochemical cell having a first electrode and a second electrode, the circuitry comprising: a first hysteretic comparator having a first comparator input for coupling to the first electrode, a second comparator input and a first comparator output for outputting a first digital output signal; a first feedback path between the first comparator output and the second comparator input, the first feedback path comprising a first loop filter configured to apply filtering to the first feedback path; a second hysteretic comparator having a third comparator input for coupling to the second electrode, a fourth comparator input and a second comparator output for outputting a second digital output signal; a second feedback path between the second comparator output and the further comparator input, the first feedback path comprising a second loop filter configured to apply filtering to the second feedback path; and processing circuitry configured to process the first and second digital output signals.

The processing circuitry may be configured to: determine a common mode signal by summing the first digital output signal and the second digital output signal.

The processing circuitry may be configured to: determine a differential signal by subtracting the first digital output signal from the second digital output signal or by subtracting the second digital output signal from the first digital output signal.

Each of the first comparator and the second comparator may be a hysteretic comparator.

Each of the first and second comparators may be a synchronous comparator, wherein the first and second comparators are clocked at a common sampling frequency.

According to another aspect of the disclosure, there is provided circuitry for characterising an electrochemical cell having a first electrode and a second electrode, the circuitry comprising: a dual differential amplifier, comprising: a first non-inverting input for coupling to the first electrode; a first inverting input for coupling to the second electrode; a second non-inverting input; a second inverting input coupled to a reference voltage; and an amplifier output; a feedback path between the amplifier output and the second non-inverting input, the feedback path comprising a loop filter configured to apply filtering to the feedback path.

The circuitry may comprise an analog-to-digital converter (ADC) having an input coupled to the amplifier output and an output for outputting a digital output representing a potential difference between the first electrode and the second electrode.

According to another aspect of the disclosure, there is provided circuitry for characterising an electrochemical cell having a first electrode, a second electrode and a non-linear response characteristic, the circuitry comprising: a first pulse-width modulated (PWM) ADC having a first input coupled to the first electrode and an output configured the output a first time encoded signal encoded based on a first voltage at the first electrode; a second pulse-width modulated (PWM) ADC having a first input coupled to the second electrode and an output configured the output a second time encoded signal encoded based on a second voltage at the second electrode; and difference circuitry configured to output digital output signal representing a difference between the first time encoded signal and the second time encoded signal.

The difference circuitry may comprise: a low pass filter configured to: filter the first time encoded signal to obtain a first binary encoded number; filter second time encoded signal to obtain a second binary encoded number; and a digital subtractor configured to subtract the second binary encoded number from the first binary encoded number to obtain the digital output signal.

According to another aspect of the disclosure, there is provided circuitry for characterising an electrochemical cell having a first electrode, a second electrode and a non-linear response characteristic, the circuitry comprising: a first programmable gain amplifier (PGA) having a first input coupled to the first electrode and an output; a second programmable gain amplifier (PGA) having a second input coupled to the second electrode and an output; and a differential amplifier having a first differential input coupled to the output of the first PGA, a second differential input coupled to the output of the second PGA, a digital output, the differential amplifier configured to output a digital output signal representing a difference between the first and second differential inputs.

According to another aspect of the disclosure, there is provided a system comprising: the circuitry described above, and the electrochemical cell.

The electrochemical cell may comprise a counter electrode and a first working electrode. The first electrode may be a first working electrode of the electrochemical cell.

The electrochemical cell may comprise an anode and a cathode. The first electrode may be the cathode.

According to another aspect of the disclosure, there is provided an electronic device, comprising the circuitry and/or the system described above.

The electronic device may comprises one of an analyte monitoring device or an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

According to another aspect of the disclosure, there is provided a method of characterising an electrochemical cell having a first electrode, a second electrode and a non-linear response characteristic, the method comprising: measure a potential difference across the electrochemical cell and output a difference voltage proportional to the measured potential difference; linearise the difference voltage and output a linearised difference signal; convert the linearised difference signal to a digital output; and determine a characteristic of the electrochemical cell based on the digital output.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of an electrochemical cell;

FIG. 2 is a schematic diagram of a known measurement circuit for characterising the electrochemical cell of FIG. 1;

FIG. 3 is a graph showing concentration vs potential difference for the cell of FIG. 1;

FIG. 4 is a graph showing concentration vs potential difference for the cell of FIG. 1 at different temperatures;

FIGS. 5 and 6 are block diagrams of a measurement circuit for characterising the electrochemical cell of FIG. 1;

FIG. 7 is an example circuit implementation of the circuits shown in FIGS. 5 and 6;

FIG. 8 graphically illustrates linearisation of a potential difference measured at the cell of FIG. 1;

FIGS. 9 and 10 are schematic diagrams of example measurement circuits for characterising the electrochemical cell of FIG. 1;

FIG. 11 illustrates a circuit for deriving common mode and differential signals from the circuit of FIG. 10;

FIGS. 12A to 12J provide examples of non-linear circuit elements; and

FIGS. 13 to 16 are schematic diagrams of example circuits for processing a potential difference signal.

### DESCRIPTION OF EMBODIMENTS

Embodiments of the present disclosure relate to the measurement of signals (such as analyte signals) in electrochemical cells. In particular, embodiments relate to improved methods and circuitry for the characterisation of electrochemical cells using potentiometry. In particular, embodiments take advantage of the non-linear characteristics of various circuit elements to linearise potential differences measurements over a spectrum of analyte concentrations. In doing so, the complexity, cost, and energy consumption of downstream processing circuitry can be reduced.

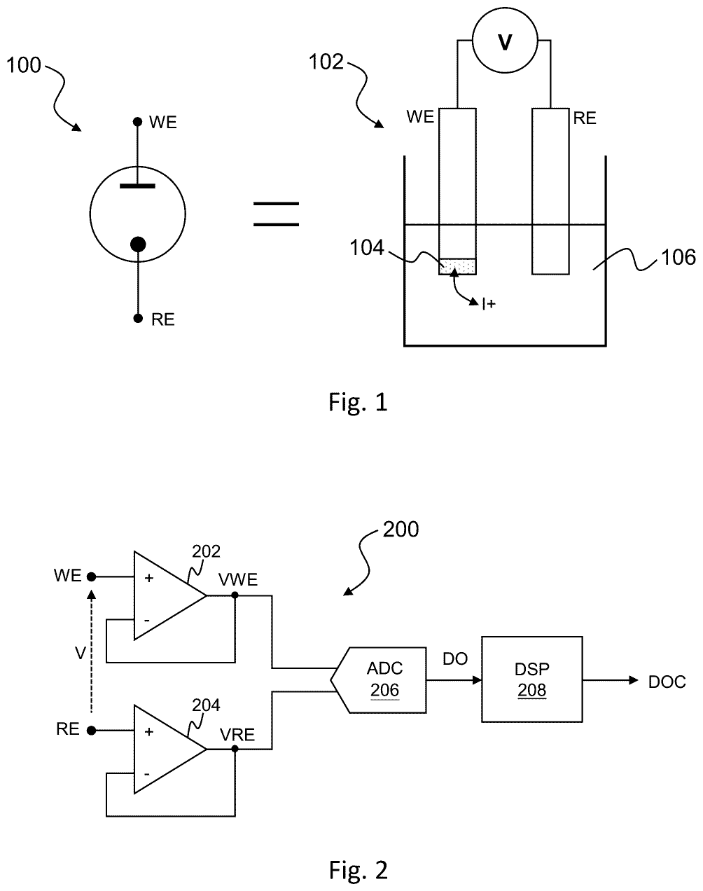

FIG. 1 illustrates a symbol for an electrochemical cell 100 comprising a working electrode WE (also known as a potentiometric electrode or indicator electrode) and a reference electrode RE. FIG. 1 also shows a schematic diagram of an example implementation of the electrochemical cell 102. The working electrode WE comprises an ion-selective membrane 104, which may be configured to uptake only a specific ion (in this case the cation, I+) from an electrolyte solution 106. As such, the potential difference between the working electrode WE and the reference electrode RE depends on the concentration of that particular ion analyte in the electrolyte solution 106.

To accurately measure the potential difference across the cell 100, as little as possible current (ideally no current) need flow into the cell 100. Hence, a typical approach to voltage measurement is to couple each of the working and reference electrodes WE, RE to high input impedance buffers which are used, in turn, to drive one or more ADCs (e.g. two single ended ADCs or one differential ADC). A digital output signal is then derived which represents the potential difference between working and reference electrode WE, RE of the cell 100.

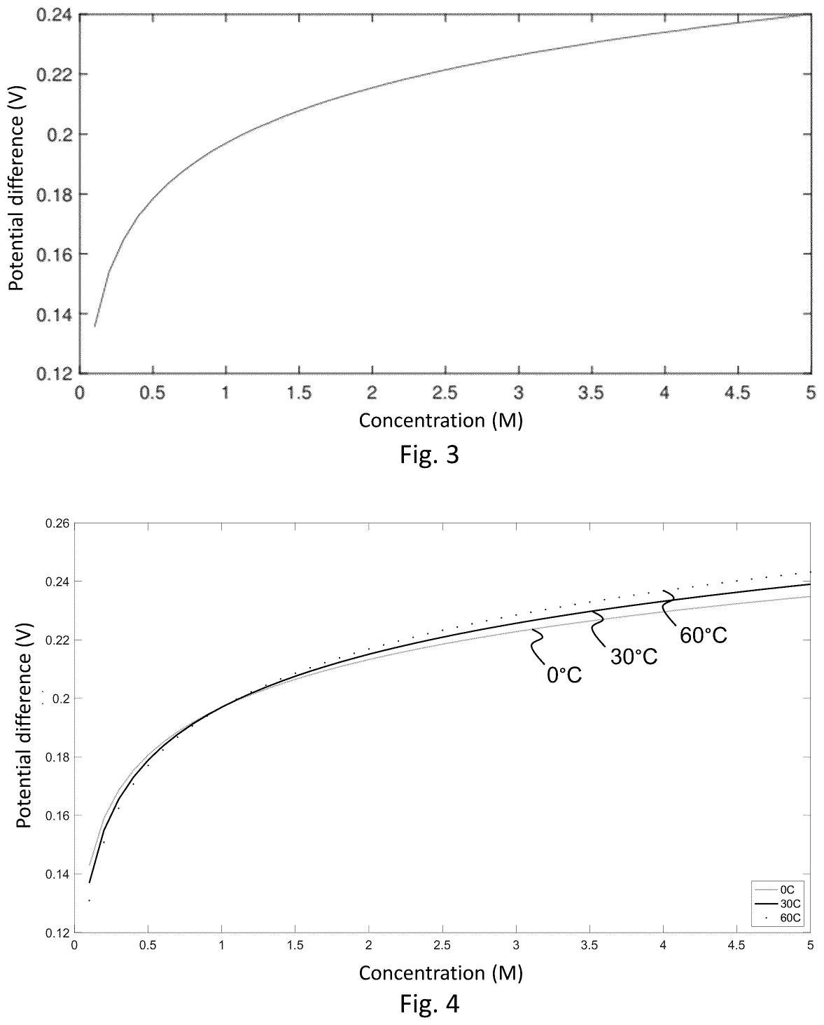

FIG. 2 illustrates an example prior art measurement circuit 200, specifically for measuring an analyte concentration in the electrochemical cell 100 shown in FIG. 1. The circuit 200 comprises a (high impedance) first buffer 202, a second (high impedance) buffer 204 and a differential ADC 206. Each of the first and second buffer 202, 204 may comprise one or more op-amps.

An input of the first buffer 202 is coupled to the working electrode WE and an output of the first buffer 202 is coupled to a first input of the ADC 206. Thus, the first buffer 202 is configured to output a working electrode voltage VWE to the ADC 206 representative of the voltage at the working electrode WE. An input of the second buffer 204 is coupled to the reference electrode WE and an output of the second buffer 204 is coupled to a second input of the ADC 206. Thus, the second buffer 204 is configured to output a reference electrode voltage VRE to the ADC 206 representative of the voltage at the reference electrode RE.

The ADC 206 outputs a digital output signal Dout which is proportional to a difference between the working electrode voltage VWE and the reference electrode voltage VWE. By measuring the potential difference V differentially, any common mode noise due to the high input impedance of the first and second buffers 202, 204 is substantially reduced when compared to single ended topologies. In other embodiments, however, the differential ADC 206 may be replaced by one or more singled ended ADCs. Additionally or alternatively, the first and second buffers 202, 204 may be replaced with alternative circuitry for measuring the voltage V between the working and reference electrodes WE, RE, so long as such circuitry exhibits a high input impedance.

Ion-selective electrodes (ISEs) are inherently non-linear in nature, as will be explained in the following paragraphs.

Referring to the cell 100, when no current flows, the cell potential E (i.e. potential difference V between the working and reference electrodes WE, RE) is given by the Nernst equation:

$$E = {E}^{0} - \frac{RT}{nF} ln Q$$

### Where:

E⁰ is the standard cell potential—a function of materials used for the working electrode WE and the electrolyte (specifically their Gibbs energy),
R is the gas constant,
F is the Faraday constant,
T is the temperature in kelvin,
N is the number of electrons transferred in the cell reaction, and Q is the reaction quotient of the cell reaction (the inverse of molar concentration, i.e. Q=1/M)

From analysis of the above equation, it can be seen that any change in cell potential E with concentration (Q) will be small. That is, the cell potential E will change by 59 mV/mole for a 10 fold change in concentration (Q).

Considering a numerical example, by way of the following reduction:

Mⁿ⁺+ne⁻→M

Assuming n=1 and the working electrode WE is a silver/silver chloride (Ag/AgCl) electrode, the standard cell potential E⁰ is +0.197 V.

Thus, for a 2M solution at 37° C. (310K), the cell potential E is given by:

$$E = 0.197 - \frac{R * 315}{F} ln \frac{1}{2} = 215 mV$$

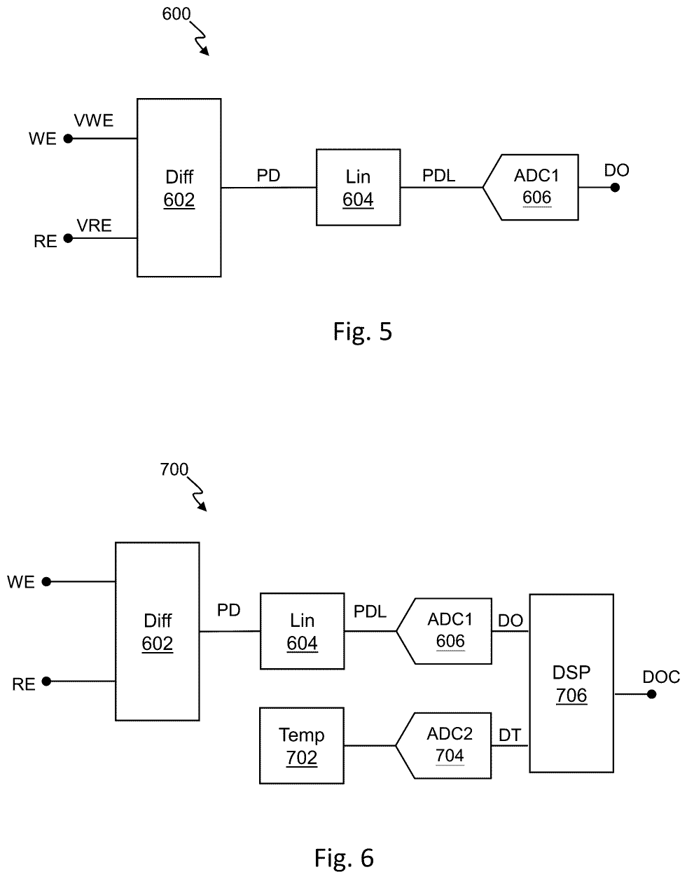

FIG. 3 is an example plot of concentration vs cell potential E (i.e. potential difference V) for the electrochemical cell 100. It can be seen that the potential difference V increases logarithmically as analyte concentration increases.

As a result, a large change in analyte concentration may result in a relatively small change in the measured output voltage V (or the digital output signal Dout). To ensure accurate measurement of small variations in potential difference V (due to potentially large variations in analyte concentration), it is known to implement the ADC 206 using relatively high-performance and/or high-resolution architecture. Such high resolution architectures tend to be complex in nature, which can lead to increased expense, higher energy consumption and larger circuit area.

The non-linearity of the digital output signal Dout may then be accounted for in the digital domain by a digital signal processor (DSP) 208 or the like configured to implement an exponential function (or exp) on the digital data to linearise the output of the cell 100 and output a compensated digital output signal DOC.

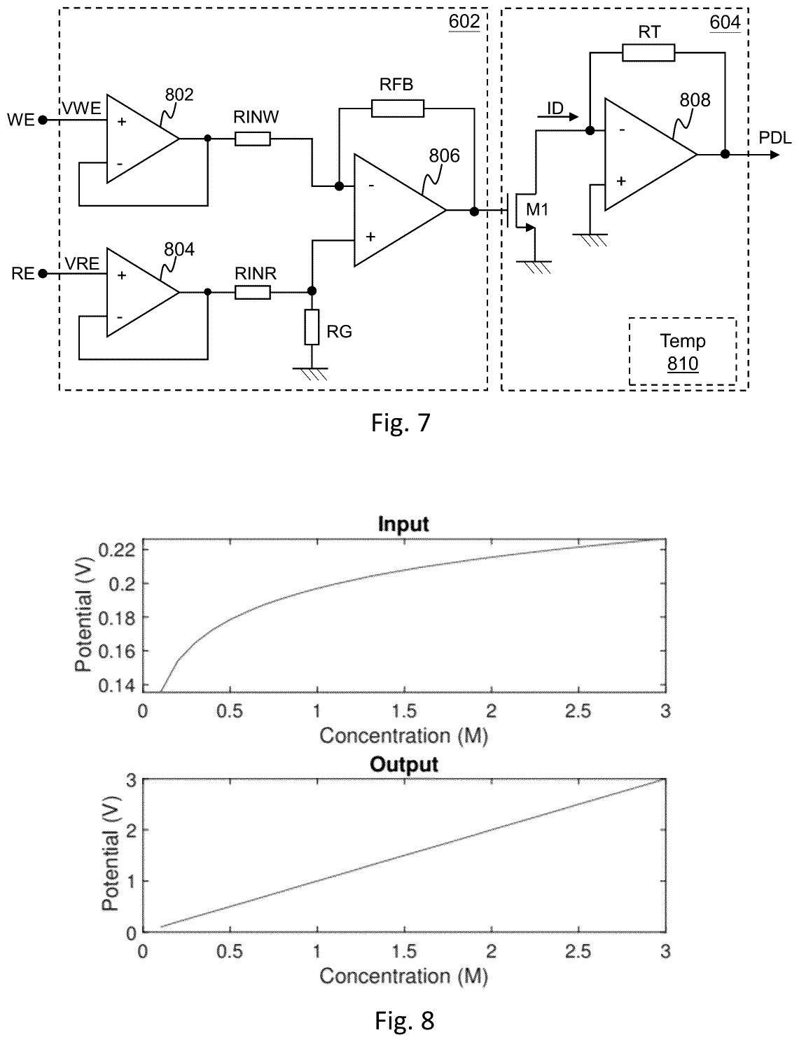

FIG. 4 is an example plot of concentration vs cell potential E (V) for the electrochemical cell 100 at different temperatures. Three plots are shown at 0° C., 30° C. and 60° C. It can be seen that for the same analyte concentration, as the temperature changes the measured potential difference V changes. As such, temperature variations at the cell 100 may lead to inaccuracies in measurement of analyte concentration if not compensated for.

Embodiments of the present disclosure aim to address or at least ameliorate one or more of the above described problems by performing linearisation of sensor data in the analog domain prior to or at the point of digitization. In doing so, the burden of addressing non-linearity in sensed data is performed in analog, thereby improving efficiency and relaxing the requirements of downstream analog to digital conversion and/or digital signal processing.

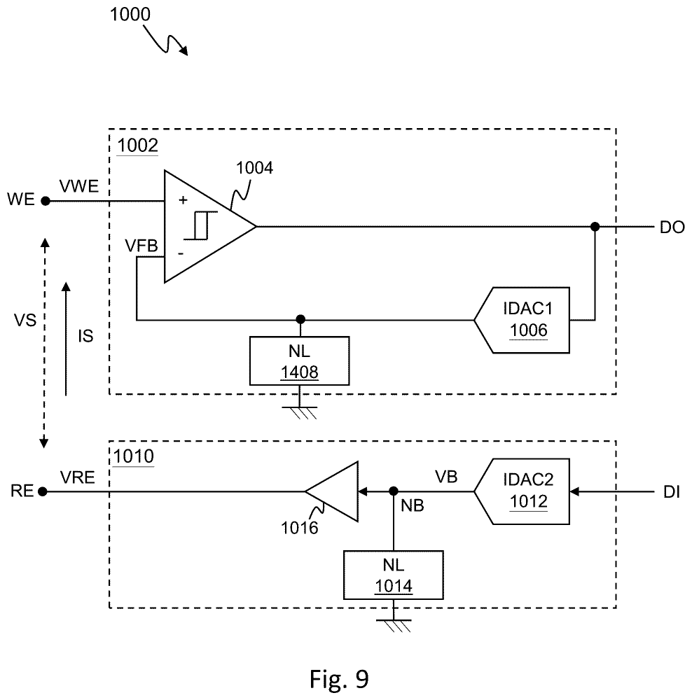

FIG. 5 is a high-level block diagram of an example measurement circuit 600 for measuring a characteristic of the electrochemical cell 100 according to embodiments of the present disclosure. The measurement circuit 600 comprises difference circuitry 602, linearisation circuitry 604 and an ADC 606. The difference circuitry 602 is configured to output a difference signal PD which is proportional to the difference between the voltage at the working electrode VWE and the voltage at the reference electrode VRE. The difference circuitry 602 may use one or more high-impedance buffers (such as those described above with reference to FIG. 2) to measure the difference between the working and reference electrode voltages VWE, VRE. The difference signal PD may be a single ended signal of a differential signal.

The difference signal is provided as an input to the linearisation circuitry 604 which is configured to linearise the difference signal in the analog domain. To do so, the linearisation circuitry 604 may be configured to implement an exponential (exp) function to linearise the difference signal PD. The linearisation circuitry 604 may be configured to implement a function which is substantially inverse to the logarithmic characteristic of the electrochemical cell 100. It will be appreciated that the linearisation circuitry 604 may implement any suitable correction or linearisation function which may be implemented in analog circuitry.

The linearisation circuitry 604 is configured to output the linearised difference signal PDL to the ADC 606, which is configured to convert the linearised difference signal PDL to a digital output signal DO which may be further processed downstream (e.g. with a DSP or the like).

In a variation of the circuit 600 shown in FIG. 5, instead of linearisation being performed by the linearisation circuitry 604, linearisation may be performed within the ADC 606 itself, the linearisation circuitry 604 omitted, as will be described in more detail below.

FIG. 6 is a high-level block diagram of a measurement circuit 700 which is a variation of the circuit 600 of FIG. 5 (like parts being denoted with like numerals). The measurement circuit 700 differs from the circuit 600 of FIG. 5 with the addition of a temperature sensor 702, a second ADC 704 and a DSP 706. The measurement circuit 700 is configured to account for temperature variations, which may otherwise affect accuracy of derivation of analyte concentration from measured working and reference electrode voltages VWE, VRE.

The temperature sensor 702 may be provided at or proximate to the cell 100 so as to measure a temperature of the electrolyte 106. A temperature signal T obtained by the temperature sensor 702 is provided to the second ADC 704. The temperature signal T is digitised by the second ADC 704 to produce digital temperature data DT which is provided to the DSP 706. The DSP 706 also receives the digital output DO from the ADC 606 representing the linearised difference signal PDF from the linearisation circuitry 604. The DSP 706 is then configured to combine the digital output DO and the digital temperature DT to provide a compensated digital output signal DOC which is compensated for temperature in the cell 100.

As noted above, linearisation is performed by the linearisation circuitry 604 in the analog domain. As such, the linearisation circuitry 604 may comprise one or more non-linear circuit elements configured to linearise a signals provided thereto. For example, such non-linear circuit elements may have a response characteristic which is substantially inverse to the non-linear response of the electrochemical cell 100. For Such non-linear circuit elements may include any element or combination of elements which exhibit exponential (or non-linear) current-voltage characteristics. include, but are not limited to: a diode; a bipolar junction transistor (BJT); a CMOS device (e.g. MOSFET) in weak inversion; and a translinear (TL) circuit or translinear loop.

Various embodiments of the present disclosure will now be described.

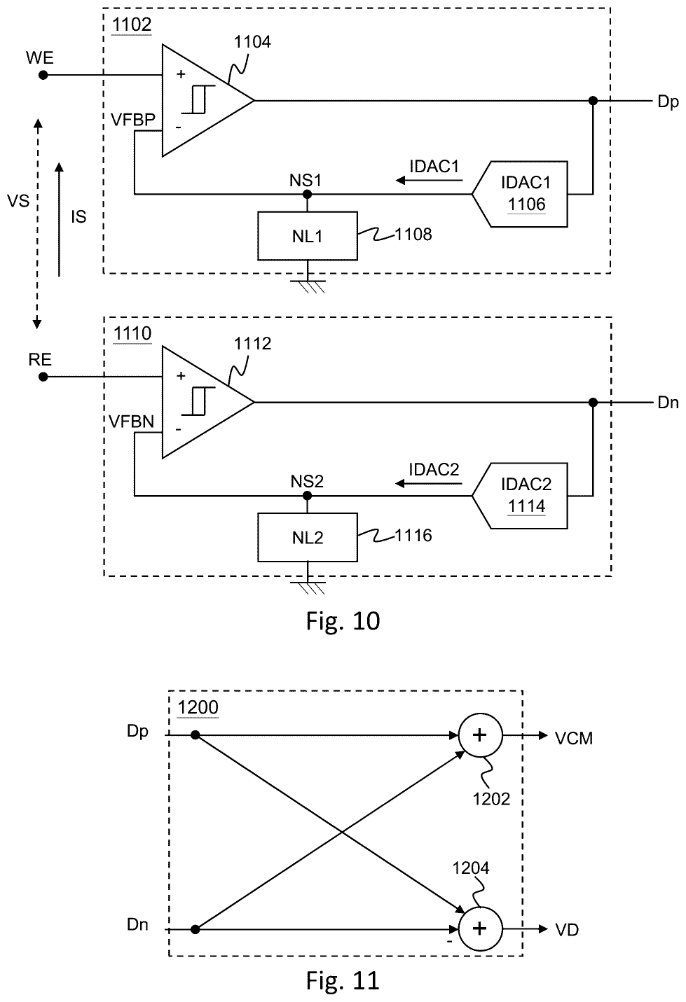

FIG. 7 is a circuit diagram of an example implementation of the difference circuitry 602 and the linearisation circuitry 604 of the circuits 600, 700 shown in FIGS. 5 and 6.

The difference circuitry comprises a (high impedance) first buffer 802, a second (high impedance) buffer 804 and a differential gain stage 806. Each of the first and second buffer 202, 204 may comprise one or more op-amps.

An input of the first buffer 202 is coupled to the working electrode WE and an output of the first buffer 202 is coupled to a first (inverting) input of the differential gain stage 806 via a first input resistor RINW. An input of the second buffer 204 is coupled to the reference electrode WE and an output of the second buffer 204 is coupled to a second (non-inverting) input of the differential gain stage 806 via a second input resistor RINR. The second input of the differential gain stage 806 is also coupled to a reference voltage (e.g. ground) via a ground resistor RG. A feedback resistor RFB is provided between an output and the first input of the differential gain stage 806 to stabilise the gain stage 806. Thus, the differential gain stage 806 outputs a difference signal PD which is proportional to the difference between the working electrode voltage VWE and the reference electrode voltage VRE. It will be appreciated that any other suitable topology for the difference circuitry 602 may be implemented without departing from the scope of the present disclosure.

The linearisation circuitry 604 in this example comprises a CMOS device M1 (in this case a MOSFET) and a transimpedance amplifier (TIA) 808. The CMOS device is configured to operation in is subthreshold range (i.e. in weak inversion). It will be appreciated that in this range of operation, the CMOS device M1 exhibits an exponential voltage-current characteristic. A gate of the CMOS device M1 is coupled to an output of the difference circuitry 602. A source of the CMOS device M1 is coupled to a reference voltage (e.g. ground). A drain of the CMOS device M1 is coupled to a first (inverting) input of the TIA 808. A second (non-inverting) input of the TIA 808 is coupled to the reference voltage (e.g. ground). A feedback resistor RT is provided between an output and the first input of the TIA 808. Thus, the TIA 808 is configured to output a voltage (as the linearised difference signal PDL) which is proportional to the drain current of the CMOS device M1.

To ensure the CMOS device M1 operates in its subthreshold region, the signal level of the difference signal PD and the reference voltage at the source of the device M1 may be controlled to ensure the gate source voltage VGS is below a threshold voltage VT for linear operation of the CMOS device M2. For example, if the threshold voltage VT of the device is 0.7 V and the reference voltage is set to zero volts (0V), the difference signal PD may be controlled (e.g. through tuning of the differential gain stage 806) to be below 0.7 V.

When in subthreshold operation, the drain current ID of the CMOS device M1 varies exponentially with the gate voltage (i.e. PD) of the CMOS device M1. Conversely, the difference signal PD provided at the gate of the CMOS device M1 has a logarithmic variation based on analyte concentration. As such, the exponential variation of the drain current ID acts to linearise the logarithmic nature of the difference signal PD, such that the voltage PDL output by the TIA 808 represents a linearised version of the difference signal PD provided to the linearisation circuitry 604.

In some embodiments, the reference voltage provided to the source may be fixed. Alternatively, the reference voltage provided to the source may be varied, for example based on one or more conditions at the cell 100. For example, the reference voltage may be varied based on temperature (e.g. at the cell 100 or at the CMOS device M1). Such variation may compensate for temperature variation of the exponential function implemented by the CMOS device M1. Additionally or alternatively, a bulk terminal of the CMOS device may be biased with a bias voltage which varies with one or more conditions, e.g. to compensate for temperature variation. Temperature may be measured by an optional temperature sensor 810, which may be the same of a different temperature sensor to the sensor 702 shown in FIG. 6, for example.

Thermal voltage UT can be defined as follows:

$${U}_{T} = \frac{kT}{q}$$

Where k is the Boltzmann constant, T is the temperature in kelvin, and q is the charge on an electron.

For the CMOS device M1 operating in the subthreshold region and having a drain source voltage VDS less than 5*UT, the drain current is given by the following equation.

$$I = {I}_{0} {e}^{\frac{{V}_{GS}}{n {U}_{T}}} . k$$

Where I0 is a constant which depends on physical characteristics of the CMOS device M1, VGS is the gate source voltage, n is the slope factor relating capacitance of the inversion layer (channel) and depletion region of the CMOS device M1, and UT is the thermal voltage.

For the example linearisation circuitry 604 described with reference to FIG. 7, the output voltage PDL is given by the following equation.

$$PDL = {I}_{0} {R}_{T} {e}^{\frac{PD}{nkT}} . k$$

Where PD is the difference signal provided to the gate of the CMOS device M1.

For small values of x, the 2,2 Pade approximation expansion of the exponential function is given by:

$${e}^{x} \approx \frac{2 + x}{2 - x}$$

Using the above expansion and neglecting small terms, the derivative of the output voltage PDL with respect to temperature can be approximated as follows:

$$\frac{dPDL}{dt} \approx {I}_{0} \frac{{R}_{T}}{T}$$

Accordingly, by varying the I0 or RT, as a function of temperature, it is possible to stabilise PDL with respect to temperature for the effects of temperature variation at the CMOS device M2. The feedback resistance RT can be varied, for example, using a variable resistor (resistor network or the like).

The constant I0 is dependent on process characteristics used to manufacture the CMOS device M1, which are likely outside of the control of a typical circuit designer. Notwithstanding, the constant I0 may be adjusted by replacing the CMOS device M1 with another device or combination of CMOS devices. For example, instead of providing the CMOS device M1, multiple CMOS devices similar to the CMOS device M1 may be provided in parallel.

Temperature compensation may also be implemented at the differential gain stage 806 of the difference circuitry 602. For example, adjusting either of the feedback resistor RFB or the ground resistor RG will adjust the gain of differential gain stage 806. Such variation of RFB and RG may be made in dependence of temperature. For example, for a desired gain G, the relationship between feedback, ground resistances RFB, RG, RT is given by the following equation.

$$\frac{{R}_{FB}}{{R}_{G}} = \frac{nF}{{R}_{T}} G$$

As such, any of these resistances RFB, RG, RT may be adjusted to account for temperature variations.

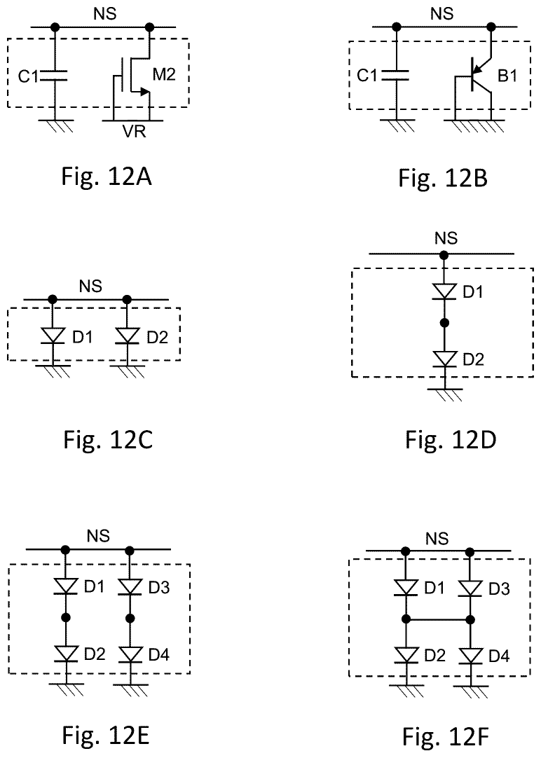

FIG. 8 graphically illustrates the linearisation of the difference signal PD by the linearisation circuitry 604. The upper plot illustrates concentration vs voltage for the difference signal PD, which can be seen to be logarithmic. The lower plot illustrates concentration vs voltage for the linearised difference signal, which can be seen to be linear.

It will be appreciated that the transfer function between the temperature data T and the resistors RFB, RG, RT may be complex and therefore may require some complex calculation. For example, each resistor value is a polynomial function of temperature. Accordingly, the relationship between resistances RFB, RG, RT and temperature may be pre-calculated and stored in a look-up table mapping temperature to preferred resistor values for at least one of RFB, RG, RT.

In the above examples, linearisation is performed by the linearisation circuitry 604 before the linearised difference signal PDL is provided to the ADC 606. In other embodiments, however, linearisation may be performed by the ADC 606 itself, the linearisation circuitry 604 omitted altogether.

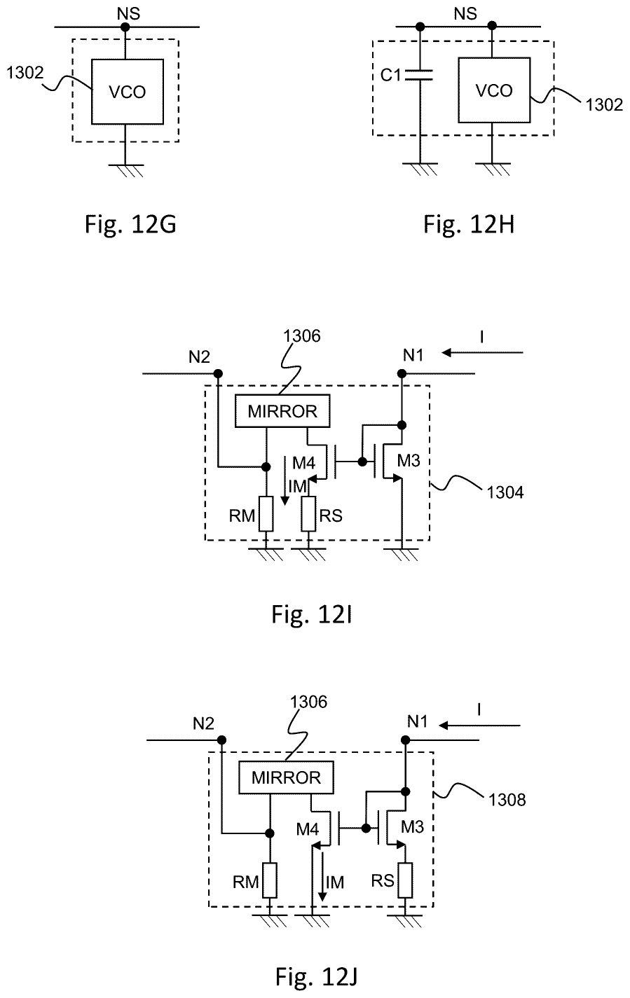

FIG. 9 is a schematic diagram of a measurement circuit 1000 configured to implement linearisation during conversion of an analog differential pair (in this case the working and reference electrode voltages VWE, VRE) to a digital output DO. The measurement circuit 1000 comprises an ADC 1002 comprising a hysteretic comparator 1004, a first current digital to analog converter (IDAC) 1006, and a first non-linear circuit element 1008. The measurement circuit 1000 further comprises compensation circuitry 1010 comprising a second IDAC 1012, a second non-linear circuit element 1014, and a (high impedance) buffer 1016.

Referring first to the ADC 1002, the hysteretic comparator 1004 comprises a first (non-inverting) input, a second (inverting) input, and an output. The first input of the comparator 1004 is configured to be coupled to the working electrode WE of the cell 100. The output of the comparator 1004 is coupled to an input of first IDAC 1006. An output of the first IDAC 1006 is coupled to the second input of the comparator 1004. Thus, the ADC 1002 operates as a pulse width modulating (PWM) ADC, the frequency of the digital output DO being proportional to the working electrode voltage VWE at the non-inverting input of the comparator 1004.

The first non-linear circuit element 1008 is coupled between the output of the IDAC 1006 and a reference voltage node (in this case coupled to ground). As such, a proportion of the current output from the IDAC 1006 flows towards the reference voltage node. The feedback voltage VFB provided to the second input of the comparator 1004 is thus compensated (or linearised) due to the current flow through the first non-linear circuit element 1008. In doing so, the first non-linear circuit element 1008 linearises non-linearity in the working electrode voltage VWE as seen in the digital output signal DO.

At the reference electrode RE, the second IDAC 1012 of the compensation circuitry 1010 is configured to output a bias voltage VB proportional to a digital input signal DI. The bias voltage VB is provided to a bias voltage node NB which is coupled to the input of a buffer 1016. The second non-linear circuit element 1014 is coupled between the bias voltage node NB and a reference voltage node (in this case also coupled to ground), thus sinking a proportion of current output from the IDAC 1012. Current flow through the second non-linear circuit element 1014 is non-linear with respect to voltage. Thus, the IDAC 1012 injects a current into the second non-linear circuit element 1014 to generate a non-linear voltage which is driven onto the reference electrode RE via the buffer 1016. The first and second non-linear circuit elements 1008, 1014 preferably have a substantially identical response characteristic (or are substantially identical in structure). As such, any variation in temperature (which would otherwise affect measurements of sense voltage VS between the two electrodes WE, RE) is compensated for since such temperature variations will affect the first and second non-linear circuit elements 1008, 1014 in a similar manner. For example, the sense voltage VS between the working and reference electrodes WE, RE is given by the Nernst equation referred to above:

$${V}_{s} = {E}_{0} - \frac{RT}{nF} ln ( \frac{1}{M} )$$

And so the bias voltage VB is given by the following equation:

$${V}_{b} = - {E}_{0} + \frac{kT}{q} ln ( \frac{{D}_{I} {I}_{DAC}}{{I}_{S}} )$$

Where IDAC is the current output from the second IDAC 1012 and IS is the sense current flowing through the cell 100. The feedback voltage VFB provided at the second input of the comparator 1004 is be given the following equation:

$${V}_{fb} = \frac{kT}{q} ln ( \frac{{D}_{O} {I}_{DAC}}{{I}_{S}} )$$

Thus, the feedback loop maintains:

$${V}_{b} + {V}_{s} = {V}_{fb}$$

$$- {E}_{0} + \frac{kT}{q} ln ( \frac{{D}_{I} {I}_{DAC}}{{I}_{S}} ) + {E}_{0} - \frac{RT}{nF} ln ( \frac{1}{M} ) = \frac{kT}{q} ln ( \frac{{D}_{O} {I}_{D A C}}{{I}_{S}} )$$

$$\frac{R}{nF} ln ( M ) = \frac{k}{q} ln ( \frac{{D}_{O}}{{D}_{I}} )$$

Thus, it can be seen that the digital output DO is not affected by temperature.

FIG. 10 a schematic diagram of a measurement circuit 1100 configured to implement linearisation during conversion of an analog differential pair (in this case the working and reference electrode voltages VWE, VRE) to a digital differential output pair Dp, Dn.

The circuit 1100 comprises a first ADC 1102 which is similar to the ADC 1002 of FIG. 9. The first ADC 1102 comprises a first hysteretic comparator 1104, a first current digital to analog converter (IDAC) 1106, and a first non-linear circuit element 1108. The first input of the first hysteretic comparator 1104 is configured to be coupled to the working electrode WE of the cell 100. The output of the first hysteretic comparator 1104 is coupled to an input of first IDAC 1106. An output of the first IDAC 1106 is coupled to the second input of the first hysteretic comparator 1104.

The circuit 1100 further comprises a second ADC 1110 which is also similar to the ADC 1002 of FIG. 9. The second ADC 1110 comprises a second hysteretic comparator 1112, a second current digital to analog converter (IDAC) 1114, and a second non-linear circuit element 1116. The first input of the second hysteretic comparator 1112 is configured to be coupled to the reference electrode RE of the cell 100. The output of the second hysteretic comparator 1112 is coupled to an input of second IDAC 1114. An output of the second IDAC 1114 is coupled to the second input of the second hysteretic comparator 1112.

Thus, in this arrangement, the first and second ADCs 1102, 1110 are configured to operate as a PWM ADC, their respective digital outputs Dp, Dn being proportional to respective working and reference electrode voltage VWE, VRE.

Using the Nernst equation, the first and second feedback voltage VFBP, VFBN may be given by the following equations.

$${V}_{fbp} = {E}_{0} + \frac{kT}{q} ln ( \frac{{D}_{p} {I}_{DAC 1}}{{I}_{S}} )$$

$${V}_{fbn} = \frac{kT}{q} ln ( \frac{{D}_{n} {I}_{DAC 2}}{{I}_{S}} )$$

Thus, the feedback loops are configured to maintain the following relationship:

$${V}_{p} - {V}_{n} = {V}_{s} = {V}_{fbp} - {V}_{fbn}$$

$${E}_{0} - \frac{RT}{nF} ln ( \frac{1}{M} ) = {E}_{0} + \frac{kT}{q} ln ( \frac{{D}_{p} {I}_{DAC 1}}{{I}_{S}} ) - \frac{kT}{q} ln ( \frac{{D}_{n} {I}_{DAC 2}}{{I}_{S}} )$$

Where the first and second IDAC current IDAC1, IDAC2 are equal:

$$\frac{R}{nF} ln ( M ) = \frac{k}{q} ln ( \frac{{D}_{p}}{{D}_{n}} )$$

As such, the differential digital output pair Dp, Dn are independent of temperature.

It will be appreciated that at low frequencies (e.g. 50 to 60 Hz), potentiometric sensors such as those described above may tend to act as antennas. This means that noise may be coupled to the inputs of respective first and second hysteretic comparators 1104, 1112. In the symmetric arrangement shown in FIG. 10, any such common mode noise coupled onto inputs via the working and reference electrodes WE, RE is substantially cancelled or significantly reduced. In addition, the differential digital output pair Dp, Dn can be used to extract both differential and common mode signals (e.g. simultaneously). The common mode signal may then be used to determine information regarding noise and the environment associated with the circuit 1100 and the cell 100.

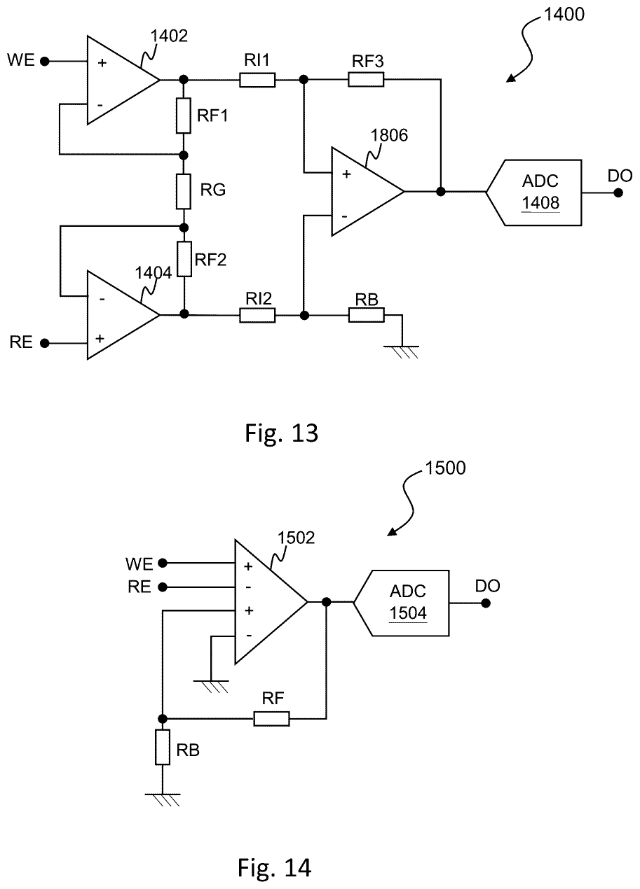

FIG. 11 is a schematic diagram of an example (conventional) circuit 1200 for deriving common mode and differential signals VCM, VD from the differential pair Dp, Dn. The digital output pair Dp, Dn may be summed at an adder 1202 to obtain the common mode signal VCM. The second digital output signal Dn may be subtracted from the first digital output signal Dp (or vice versa) at a subtractor 1204 to obtain the differential signal VD.

As noted above, the various non-linear circuit elements may have a response characteristic which is substantially inverse to the non-linear response of the electrochemical cell 100. Such non-linear circuit elements may include any element or combination of elements which exhibit exponential (or other non-linear) current-voltage characteristics. Such element(s) may include one or more diodes; one or more bipolar junction transistor (BJT), one or more CMOS devices (e.g. MOSFET) in weak inversion, one or more translinear (TL) circuits (or translinear loop), one or more voltage controlled oscillators, or any combination thereof.

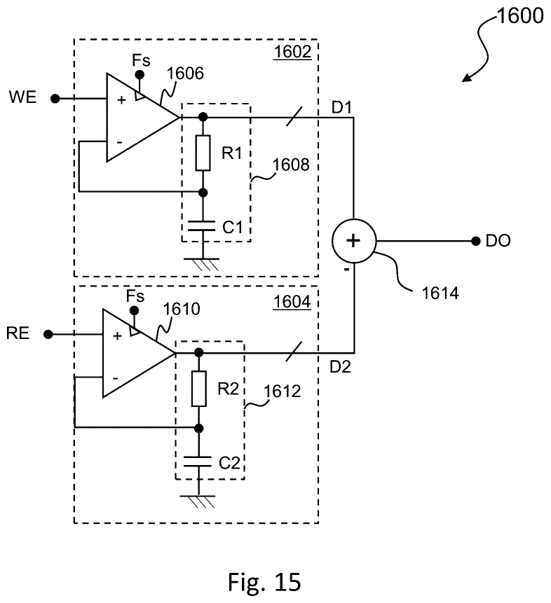

FIGS. 12A to 121 provide various non-limiting examples of non-linear circuit elements, each providing a different non-linear response. By adjusting the arrangement of components making up the non-linear circuit element, the shape of the non-linear response characteristic can in turn be adjusted.

In FIG. 12A, a CMOS device M2 is provided in parallel with a capacitor C1. The gate and source of the CMOS device M2 are coupled to a reference voltage node held at a reference voltage VR. The drain of the CMOS device M2 is coupled to a sink node NS. The capacitor C1 is coupled between the reference voltage node and the sink node NS. The reference voltage VR may be chosen to as to provide a bias voltage to the gate of the device M2 which is less than a threshold voltage VT of the device (typically around 700 mV for standard CMOS). For example, the reference voltage VR may be around half the threshold voltage VT. For example, for a threshold voltage VT of 700 mV, the reference voltage VR may be set to 350 mV. The reference voltage VR may be adjusted in dependence on one or more conditions. Such conditions may include one or more of temperature, non-linearity, etc.

FIG. 12B is a variation of the arrangement in FIG. 12A, the CMS device M2 being replaced with a BJT B1. The base and collector of the BJT B1 are coupled to the reference voltage node (in this case ground), and the drain of the BJT B1 is coupled to a sink node NS. It will be appreciated that the BJT B1 may be implemented as a PNP device (as shown) or alternatively a NPN device.

In FIG. 12C, first and second diodes D1, D2 are provided in parallel, the anodes of the diodes D1, D2 coupled to the sink node NS, the cathodes of the diodes D1, D2 coupled to the reference voltage node (e.g. ground).

In FIG. 12D, first and second diodes D1, D2 are provided in series between the sink node NS and the reference voltage node (e.g. ground). The anode of the first diode D1 is coupled to the sink node NS. The cathode of the first diode D1 is coupled to the anode of the second diode D2. The cathode of the second diode D1 is coupled to the reference voltage node.

FIG. 12E is a variation of the arrangement of FIG. 12D. In addition to the first and second diodes D1, D2, third and fourth diodes D3, D4 are provided in series between the sink node NS and the reference voltage node (e.g. ground). The anode of the third diode D3 is coupled to the sink node NS. The cathode of the third diode D3 is coupled to the anode of the fourth diode D4. The cathode of the fourth diode D4 is coupled to the reference voltage node. Thus, the series combination of the third and fourth diodes D3, D4 are provided in parallel with the series combination of the first and second diodes D1, D2.

FIG. 12F is a variation of the arrangement shown in FIG. 12E, differing only in that the anodes of the first and third diodes D1, D3 (and therefore the cathodes of the second and fourth diodes D2, D4) are coupled together.

In FIG. 12G, a voltage controlled oscillator (VCO) 1302 is coupled between the sink node NS and the reference voltage node (e.g. ground). The current to voltage characteristic of the VCO 1302 may be defined as follows, where VNS is the voltage at the sink node NS:

i∝V_{NS}²

FIG. 12H shows a variation of the arrangement shown in FIG. 12G in which a capacitor C1 is provided in parallel with the VCO 1302.

FIG. 12I illustrates a non-linear circuit element 1304 which may be coupled into the feedback look via first and second nodes N1, N2. For example, with reference to FIG. 10, instead of providing the non-linear element 1108 coupled between the sink node NS1 and the reference voltage (ground). The non-linear circuit element 1304 of FIG. 121 may be provided in series in the feedback loop between the first IDAC 1106 and the inverting input of the comparator 1104. For example, the sink node N1 of the non-linear circuit element 1304 may be coupled to the output of the first IDAC 1106 and the second node N2 of the non-linear circuit element 1304 may be coupled to the inverting input of the comparator 1104.

The non-linear circuit element 1304 comprises a first CMOS device M3, a second CMOS device M4, a current mirror 1306, a source resistor RS, and a mirror resistor RM. A drain and a gate of the first CMOS device M3 and a gate of the second CMOS device M4 are coupled together and to the first node N1. A source of the first CMOS device M3 is coupled to a reference voltage node (e.g. ground). A drain of the second CMOS device M4 is coupled to one side of the current mirror 1306. A source of the second CMOS device M4 is coupled to the reference voltage node via a source degeneration resistor RS. As such, the second CMOS device M3 is source degenerated. The other side of the current mirror 1306 is coupled to the reference voltage via a mirror resistor RM and to the second node N2. The drain source voltage VDS across the first CMOS device M3 is proportional to the square root of the current at the first node N1. The current mirror acts to mirror the current IM through the second CMOS device M4 at the second node N2.

FIG. 12J illustrates a non-linear circuit element 1308 which is a variation of the circuit element 1304 of FIG. 12I, like parts having been given like numbering. In contrast to the circuit element 1304 of FIG. 12I, the source degeneration resistor RS has been moved from being connected between the source of the second CMOS device M4 and the reference voltage node to being connected between the source of the first CMOS device M3 and the reference voltage node. In doing so, the first CMOS device M3 is source degenerated, instead of the second CMOS device M4.

As noted above, potentiometric measurements are preferably performed differentially so as to eliminate or at least reduce common mode noise. FIG. 7 above provides one example implementation of the difference circuitry 602 for differential measurement of voltages at the working and reference electrodes WE, RE. Alternative implementations of the difference circuitry 602 will now be described.

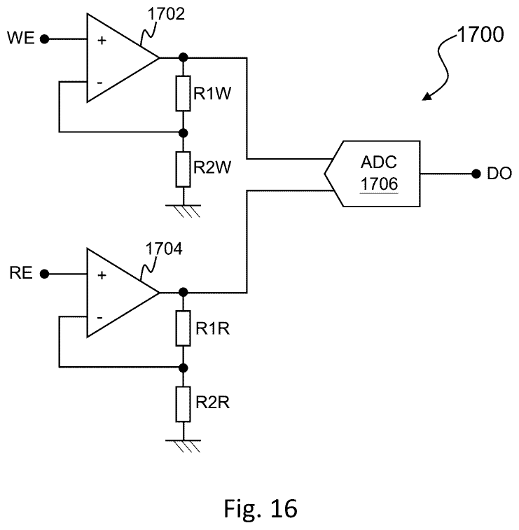

FIG. 13 illustrates a measurement circuit 1400 which is based on a well-known instrumentation amplifier. The circuit 1400 comprise first and second input buffers 1402, 1404, a gain stage 1406 and an ADC 1408.

The first input buffer 1402 has a first input configured to be coupled to the working electrode WE of the cell 100. A second input and an output of the first input buffer 1402 are coupled together via a first feedback resistor RF1.

The second input buffer 1404 has a first input configured to be coupled to the working electrode RE of the cell 100. A second input and an output of the first input buffer 1402 are coupled together via a second feedback resistor RF2. The second inputs of each of the first and second input buffers 1402, 1404 are coupled together via a gain resistor RG.

The gain stage 1406 comprises a first input coupled to the output of the first input buffer 1402 via a first input resistor RI1, a second input coupled to the output of the second input buffer 1404 via a second input resistor RI2, and an output coupled to an input of the ADC 1408. The output and first input of the gain stage 1406 are coupled together via a third feedback resistor RF3. The second input of the gain stage 1406 is coupled to a reference voltage (e.g. ground) via a bias resistor RB.

The ADC 1408 is configured to output a digital output signal DO based on the analog input signal received from the gain stage 1406.

The provision of input buffers 1402, 1404 reduces or eliminates the requirement for input impedance matching. Additionally, this arrangement exhibits low DC offset, low drift, high open loop gain and high input impedance, making it suitable for measuring the potential difference across the cell 100. Gain can be controlled efficiently by adjusting the value of the gain resistor RG.

FIG. 14 illustrates a measurement circuit 1500 comprising a dual differential amplifier 1502 having a first non-inverting input to be coupled to the working electrode WE and a first inverting input to be coupled to the reference electrode RE. A second non-inverting input of the dual differential amplifier 1502 is coupled to a reference voltage (e.g. ground) via a bias resistor VB and additionally coupled to an output of the dual differential amplifier 1502 via a feedback resistor RF. A second inverting input of the dual differential amplifier 1502 is coupled to the reference voltage (e.g. ground) or a different reference voltage (not shown). The output of the dual differential amplifier 1502 is provided as an input to an ADC 1504. By providing a single dual differential amplifier 1502 instead of two discrete differential amplifiers, duplication of circuit components can be reduced. For example, the dual differential amplifier 1502 may share all stages post-input, thus reducing total power draw and area. The dual differential amplifier arrangement shown in FIG. 14 may therefore be more thermodynamically efficient when compared to designs implementing multiple single channel differential amplifiers.

FIG. 15 illustrates a measurement circuit 1600 comprising first and second PWM ADCs 1602, 1604.

The first ADC 1602 comprises a first comparator 1606 having a first (non-inverting) input to be coupled to the working electrode WE of the cell 100, an output, and a second (inverting) input. A feedback path is provided between the output and second input of the first comparator 1606. A first loop filter 1608 comprising a first resistor R1 and a first capacitor C1 is provided in the feedback path. The first resistor R1 is coupled between the output and the second input of the first comparator 1606. The first capacitor C1 is coupled between the second input of the first comparator 1606 and a reference voltage (e.g. ground).

The second ADC 1604 comprises a second comparator 1610 having a first (non-inverting) input to be coupled to the working electrode WE of the cell 100, an output, and a second (inverting) input. A feedback path is provided between the output and second input of the second comparator 1610. A second loop filter 1612 comprising a second resistor R2 and a second capacitor C2 is provided in the feedback path. The second resistor R2 is coupled between the output and the second input of the second comparator 1610. The second capacitor C2 is coupled between the second input of the second comparator 1610 and the reference voltage (e.g. ground).

The first and second ADCs 1602, 1604 are clocked at a common sampling frequency Fs. Thus, the first and second ADCs 1602, 1604 are configured to generate respective first and second PWM signals that alternative between different two signal levels which encode the difference between a signal level at respective first inputs of the comparators 1606, 1610 and a signal level of the feedback signals at respective second inputs of the comparators 1606, 1610 by the proportion of time spent in each output state. First and second time encoded signals D1, D2 from respective outputs of the first and second comparators 1606, 1610 are provided to a digital subtractor 1614 which is configured to subtract the second time encoded signal D2 from the first time encoded signal d1 to provide the digital output DO. The digital subtractor 1614 may implement a differential operation to determine a difference between the first and second time encoded signals D1, D2. For example, a low pass filter may be used to convert the first and second time encoded signals D1, D2 into binary encoded numbers, which can then be use with a standard digital subtractor.

FIG. 16 is a schematic diagram illustrates a measurement circuit 1700 comprising first and second programmable gain amplifiers (PGAs) 1702, 1704 and a differential ADC 1706. The first PGA 1702 comprises a first (non-inverting) input to be coupled to the working electrode WE, an output, and a second (inverting) input. The second input is coupled to the output via a first resistor R1W and to a reference voltage (ground) via a second resistor R2W. The output of the first PGA 1702 is coupled to a first differential input of the differential ADC 1706.

The second PGA 1704 comprises a first (non-inverting) input to be coupled to the reference electrode RE, an output, and a second (inverting) input. The second input of the second PGA 1704 is coupled to the output via a third resistor R1R and to a reference voltage (ground) via a second resistor R2R. The output of the second PGA 1702 is coupled to a second differential input of the differential ADC 1706.

The differential ADC 1706 is configured to convert a difference between outputs of respective first and second PGAs 1702, 1704 into a digital output DO.

Whilst the measurement circuit 1700 shown in FIG. 16 is not configured to apply linearisation, the circuit 1700 may be modified to implement such linearisation. For example, a non-linear circuit element may be coupled in parallel with the second and fourth resistors R2W, R2R between, i.e. between respective second inputs of the first and second PGAs 1702, 1704 and the reference voltage.

Additionally, or alternatively, dynamic range extension (DRE) may be implemented by increasing the gain of the PGAs 1702, 1704 at low input signal levels. Any increase in gain at the PGAs 1702, 1704 may be compensate for in the digital domain, i.e. after the ADC 1706.

In the embodiments described herein, the electrochemical cells 100, 200 have been described in the form of potentiometric cell comprising counter and working electrodes CE, WE. It will be appreciated that embodiments of the present disclosure are not limited to such cells and extend to other types of cells, such as electrochemical cells acting as a power source (i.e. a battery).

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for characterising an electrochemical cell having a first electrode, a second electrode and a non-linear response characteristic, the circuitry comprising:
difference circuitry configured to measure a potential difference across the electrochemical cell and output a difference voltage proportional to the measured potential difference;
compensation circuitry configured to linearise the difference voltage and output a linearised difference signal; and
a first analog-to-digital converter (ADC) configured to convert the linearised difference signal to a digital output.

2. Circuitry of claim 1, wherein a response characteristic of the compensation circuitry is substantially inverse to the non-linear response of the electrochemical cell.

3. Circuitry of claim 1, wherein the non-linear response characteristic of the electrochemical cell is a logarithmic response characteristic, and wherein the response characteristic of the compensation circuitry is an exponential response characteristic.

4. Circuitry of claim 3, wherein the exponential response characteristic is provided by a non-linear circuit element of the compensation circuitry.

5. Circuitry of claim 4, wherein the non-linear circuit element comprises a diode or a voltage controlled oscillator (VCO) or a translinear loop.

6. Circuitry of claim 4, wherein the non-linear circuit element comprises a bipolar junction transistor (BJT), wherein a base of the BJT is coupled to a collector of the BJT.

7. (canceled)

8. Circuitry of claim 4, wherein the non-linear circuit element comprises a field effect transistor (FET) configured for operation in a subthreshold mode, wherein a gate of the FET is coupled to a source or a drain of the FET.

9-10. (canceled)

11. Circuitry of claim 1, wherein the difference circuitry comprises a first amplifier comprising:
a first input for receiving a first voltage derived from the first electrode; and
a second input for receiving a second voltage derived from the second electrode.

12. Circuitry of claim 11, wherein the first amplifier is a dual differential amplifier, wherein the first input is a first non-inverting input, and wherein the second input is a first inverting input, wherein the first amplifier further comprises:
a second non-inverting input coupled to an output of the first amplifier via a feedback resistor, the second non-inverting input coupled to a first reference voltage via a bias resistor; and
a second inverting input coupled to the reference voltage or a second reference voltage.

13-14. (canceled)

15. Circuitry of claim 1, wherein the difference circuitry comprises:
a first pulse-width modulated (PWM) ADC having a first input coupled to the first electrode and an output configured the output a first time encoded signal encoded based on a first voltage at the first electrode; and
a second pulse-width modulated (PWM) ADC having a first input coupled to the second electrode and an output configured the output a second time encoded signal encoded based on a second voltage at the second electrode.

16. Circuitry for processing a signal from a sensor having a non-linear response characteristic, the circuitry comprising:
an analog-to-digital converter (ADC) comprising:
an ADC input;
an ADC output; and
a feedback path between the ADC input and the ADC output, the feedback path comprising a digital to analog converter (DAC); and
a non-linear circuit element coupled between the feedback path and a reference voltage, the non-linear circuit element configured to compensate for the non-linear response characteristic of the sensor.

17. (canceled)

18. Circuitry of claim 16, wherein the non-linear circuit element comprises one or more diodes, the one or more diodes comprising:
a cathode coupled to the feedback path; and
an anode coupled to the reference voltage.

19. Circuitry of claim 16, wherein the non-linear circuit element comprises a PNP bipolar junction transistor (BJT) comprising:
an emitter coupled to the feedback path; and
a base and a collector, the base and the collector coupled to the reference voltage.

20. Circuitry of claim 16, wherein the non-linear circuit element comprises a NPN bipolar junction transistor (BJT) comprising:
an emitter coupled to the reference voltage; and
a base and a collector, the base and the collector coupled to the emitter, or wherein the non-linear circuit element comprises a field effect transistor (FET) configured for operation in a subthreshold mode, the FET comprising a gate, a source, and a drain;
wherein the gate and a first one of the source and drain are coupled to the reference voltage; and
wherein a second one of the source and drain different from the first one is coupled to the feedback path.

21. (canceled)

22. Circuitry of claim 16, wherein the non-linear circuit element comprises a diode or a voltage controlled oscillator (VCO), or a translinear loop.

23. Circuitry for characterising an electrochemical cell having a first electrode and a second electrode, the circuitry comprising:
a first hysteretic comparator having a first comparator input for coupling to the first electrode, a second comparator input and a first comparator output for outputting a first digital output signal;
a first feedback path between the first comparator output and the second comparator input, the first feedback path comprising a first loop filter configured to apply filtering to the first feedback path;
a second hysteretic comparator having a third comparator input for coupling to the second electrode, a fourth comparator input and a second comparator output for outputting a second digital output signal;
a second feedback path between the second comparator output and the further comparator input, the first feedback path comprising a second loop filter configured to apply filtering to the second feedback path; and
processing circuitry configured to process the first and second digital output signals.

24. Circuitry of claim 23, wherein the processing circuitry is configured to:
determine a common mode signal by summing the first digital output signal and the second digital output signal; and
determine a differential signal by subtracting the first digital output signal from the second digital output signal or by subtracting the second digital output signal from the first digital output signal.

25. (canceled)

26. Circuitry of claim 23, wherein each of the first comparator and the second comparator is a hysteretic comparator.

27. (canceled)

28. Circuitry for characterising an electrochemical cell having a first electrode and a second electrode, the circuitry comprising:
a dual differential amplifier, comprising:
a first non-inverting input for coupling to the first electrode;
a first inverting input for coupling to the second electrode;
a second non-inverting input;
a second inverting input coupled to a reference voltage; and
an amplifier output;
a feedback path between the amplifier output and the second non-inverting input, the feedback path comprising a loop filter configured to apply filtering to the feedback path.

29. (canceled)

30. Circuitry for characterising an electrochemical cell having a first electrode, a second electrode and a non-linear response characteristic, the circuitry comprising:
a first pulse-width modulated (PWM) ADC having a first input coupled to the first electrode and an output configured the output a first time encoded signal encoded based on a first voltage at the first electrode;
a second pulse-width modulated (PWM) ADC having a first input coupled to the second electrode and an output configured the output a second time encoded signal encoded based on a second voltage at the second electrode; and
difference circuitry configured to output digital output signal representing a difference between the first time encoded signal and the second time encoded signal.

31. Circuitry of claim 30, wherein the difference circuitry comprises:
a low pass filter configured to:
filter the first time encoded signal to obtain a first binary encoded number;
filter second time encoded signal to obtain a second binary encoded number; and
a digital subtractor configured to subtract the second binary encoded number from the first binary encoded number to obtain the digital output signal.

32. Circuitry for characterising an electrochemical cell having a first electrode, a second electrode and a non-linear response characteristic, the circuitry comprising:
a first programmable gain amplifier (PGA) having a first input coupled to the first electrode and an output;
a second programmable gain amplifier (PGA) having a second input coupled to the second electrode and an output; and
a differential amplifier having a first differential input coupled to the output of the first PGA, a second differential input coupled to the output of the second PGA, a digital output, the differential amplifier configured to output a digital output signal representing a difference between the first and second differential inputs.

33. A system comprising:
the circuitry of claim 1;
the electrochemical cell.

34-35. (canceled)

36. An electronic device, comprising the circuitry of claim 1, wherein the electronic device comprises one of an analyte monitoring device or an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

37-38. (canceled)
